(19) United States
(12) Patent Application Publication
(10) Pub. No.: US 2011/0049714 A1
(43) Pub. Date: Mar. 3, 2011

(54) Illuminant

(75) Inventors: Georg Diamantidis, Dernbach (DE); Frederic Tonhofer, Bertrange (LU)

(73) Assignee: NOCTRON SOPARFI S.A., Bridel (LU)

(21) Appl. No.: 12/528,431

(22) PCT Filed: Oct. 11, 2007
(86) PCT No.: PCT/EP2007/008833

§ 371 Date: Nov. 15, 2010

(30) Foreign Application Priority Data
Feb. 23, 2007 (DE) 10 2007 009 351.0

(51) Int. Cl. H01L 23/532; H01L 21/768

(52) U.S. Cl. 257/746; 438/610; 257/E23.155; 257/E21.575

(57) ABSTRACT

The invention relates to an illuminant (40) comprising a standardised connection socket (42) and a cover (50) consisting of a light-permeable material defining an inner chamber (52). A light chip arrangement (10; 110) comprising at least one semiconductor structure (14; 114) is contacted between contact regions (48a, 48b) of at least two supply lines (44a, 44b).

The invention concerns an illuminant according to the pre-characterizing clause of Claim 1.

Such illuminants are widely used in many fields of use, and are characterized by a connector base which is adapted to the appropriate field of use, and which can work with a corresponding holder.

Between the contact regions of the supply lines, usually a lighting element, e.g. a spiral-wound filament, is contacted.

Such illuminants often have the disadvantage that whereas the costs of acquiring them are sometimes high, they have only a relatively short lifetime, since the lighting element is delicate, and is no longer functional after, for instance, 1,000 hours of operation.

The object of the invention is to create an illuminant of the above-mentioned kind, with an increased lifetime.

In the case of an illuminant of the above-mentioned kind, this is achieved by the contact regions of the supply lines contacting a light chip arrangement, which includes at least one light-emitting semiconductor structure.

As the light-emitting semiconductor structure, semiconductor crystals, with a p-n junction, which emit light when voltage is applied, are considered. Such semiconductor crystals are characterized by a high energy yield combined with a long lifetime.

Advantageous further developments of the invention are given in subclaims.

By the action according to Claim 2, via the supply lines, as well as the voltage supply to the light chip arrangement, heat removal from the light chip arrangement, which becomes heated when voltage is applied to it, can be ensured.

Known contacting methods can be used advantageously if the contacting of the supply lines with the lighting arrangement is in the form given in Claim 3.

Alternatively, it can be advantageous to form this contacting as described in Claim 4, to avoid higher temperature stresses on the light chip arrangement.

Higher lighting power of the illuminant can be advantageously achieved by the actions according to Claim 5 or Claim 6.

If multiple semiconductor structures are combined in one light chip arrangement, it is advantageous if they are connected to each other conductingly according to Claim 7. Such connection is more stable than connection by means of bonds, as is often conventional in the case of semiconductor structures.

Claim 8 brings the advantage that the vapour-deposited connections have uniform thickness, although they must overcome a height difference on the chip.

If the light chip arrangement is in the form given in Claim 9, light radiation in essentially all spatial directions can be achieved.

The further development of the invention according to Claim 9 has the advantage that a greater quantity of light is obtained, and at the same time, with the operating voltage of the illuminant, higher ranges, for which standard voltage sources such as storage batteries, power supply units and standard mains power lines are available, are reached.

According to Claim 10, the operating voltage of the illuminant can be adjusted to the output voltage of common voltage sources.

An illuminant according to Claim 11 radiates light forwards and backwards.

Advantageous materials for the base substrate are given in Claim 12.

By the action according to Claim 13, good heat removal from the light chip arrangement outward through the inner chamber of the illuminant is achieved.

If the wavelength of the light which the light chip arrangement emits does not agree with a desired wavelength, it can be adjusted by the action according to Claim 14. Phosphor particles absorb radiation which strikes them, and emit radiation of at least one other wavelength. Thus with a suitable choice of phosphor particles or phosphor particle mixtures, the radiation which the light chip arrangement emits can be converted into radiation with a different spectrum.

According to Claim 15, homogeneous distribution of the phosphor particles can be ensured in a simple way.

According to Claims 16 and 17, the phosphor particles are fixed in their homogeneous distribution.

According to Claim 18, the efficiency of the colour specification of the light by the phosphor particles is improved.

In this case, the desired distance between phosphor particles and light-emitting semiconductor structures can be securely and lastingly set according to Claim 19.

In this case, a translucent substrate, which carries the semiconductor structures and is provided in any case, according to Claim 20 can simultaneously ensure the desired distance on one side of the light chip arrangement.

In the case of an illuminant according to Claim 21, the light-emitting semiconductor structures are connected by tracks which run parallel to the substrate plane. These can also be shown specially well and specially evenly by vapour deposition (no shading of the metal vapour).

Below, embodiments of the invention are explained in more detail on the basis of the drawings, in which:

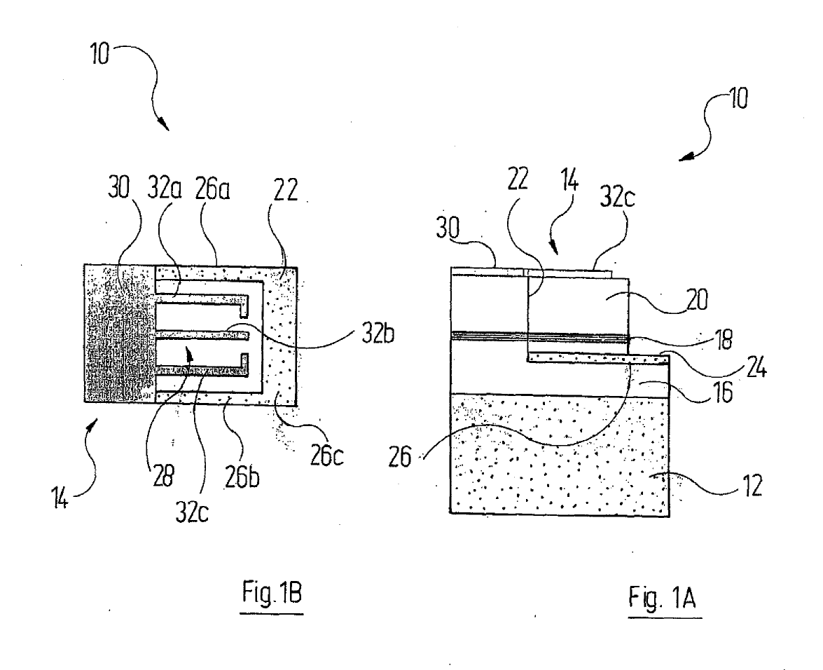

FIG. 1A shows a side view of a light chip arrangement with a semiconductor structure;

FIG. 1B shows a plan view of the light chip arrangement according to FIG. 1A;

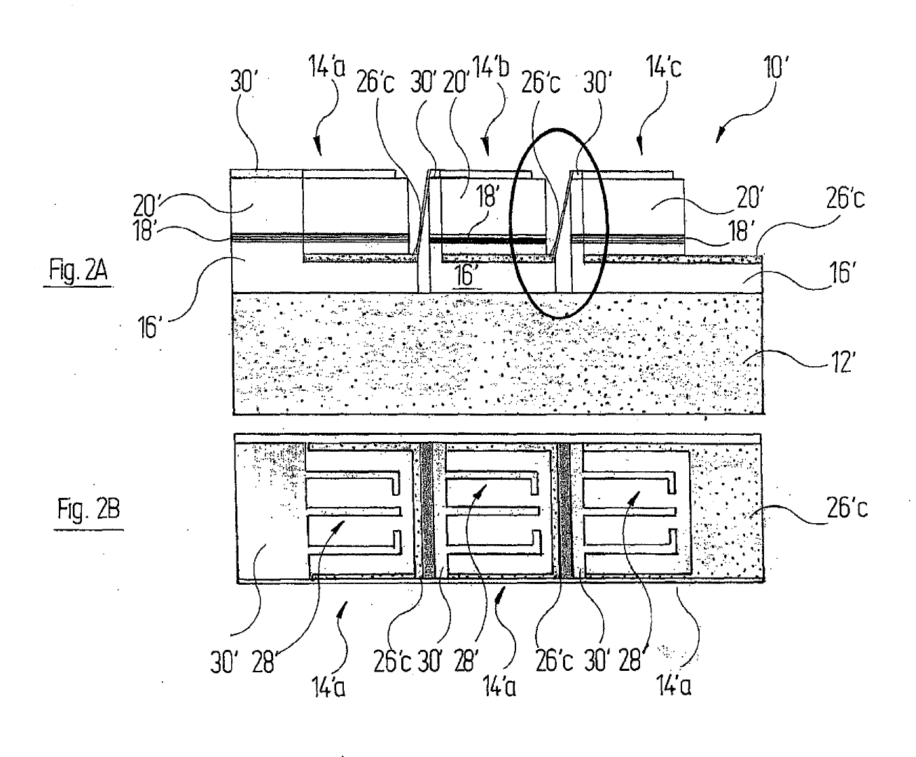

FIG. 2A shows a modified light chip arrangement with three semiconductor structures;

FIG. 2B shows a plan view of the modified light chip arrangement according to FIG. 2A;

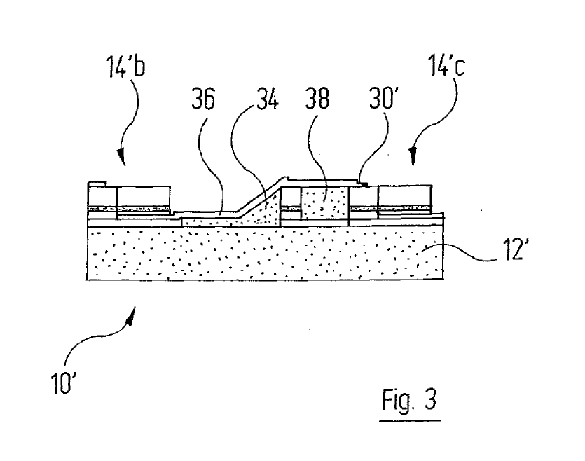

FIG. 3 shows a detailed view of the area enclosed by an ellipse in FIG. 2A between two semiconductor structures;

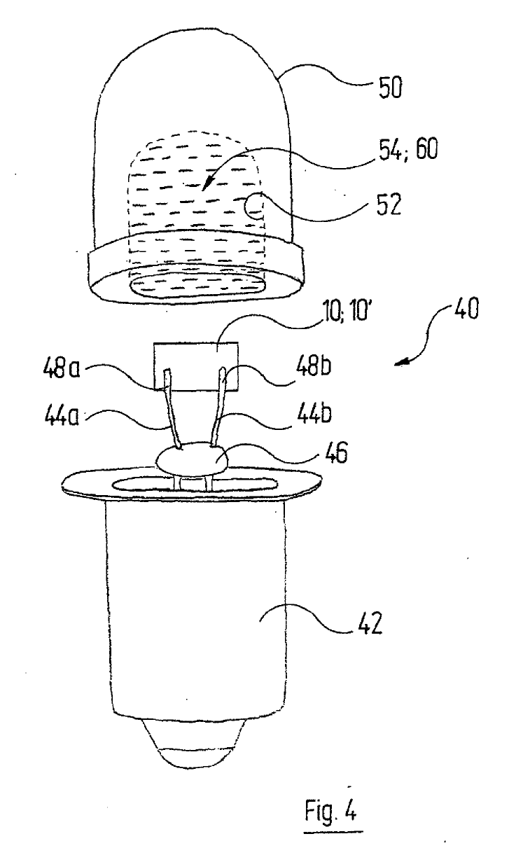

FIG. 4 shows an illuminant with a standardised bayonet base, supply lines contacting a light chip arrangement, and a transparent bulb being shown separately from the bayonet base;

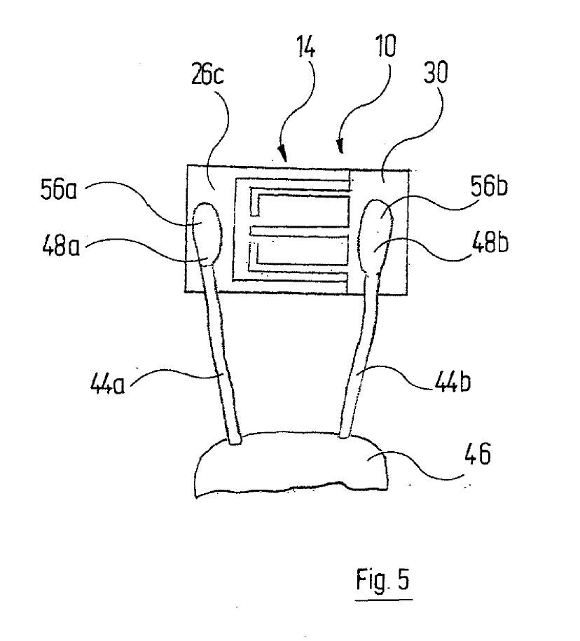

FIG. 5 shows a detailed view of the illuminant according to FIG. 4 at an enlarged scale, the supply lines contacting the light chip arrangement according to FIGS. 1A and 1B;

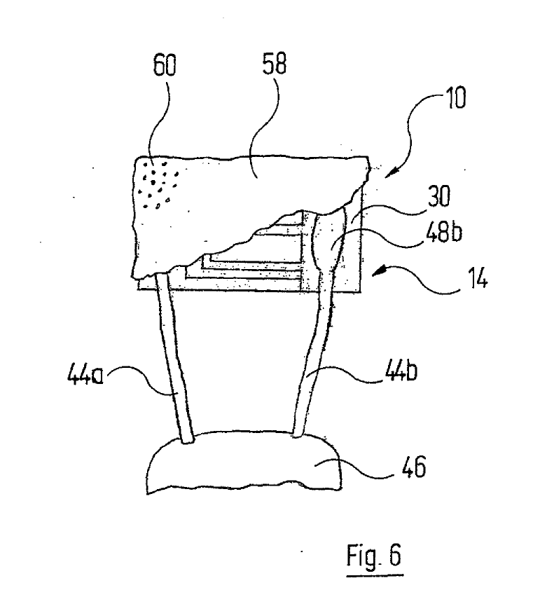

FIG. 6 shows a view corresponding to FIG. 5, the light chip arrangement being sheathed in a material with phosphor particles;

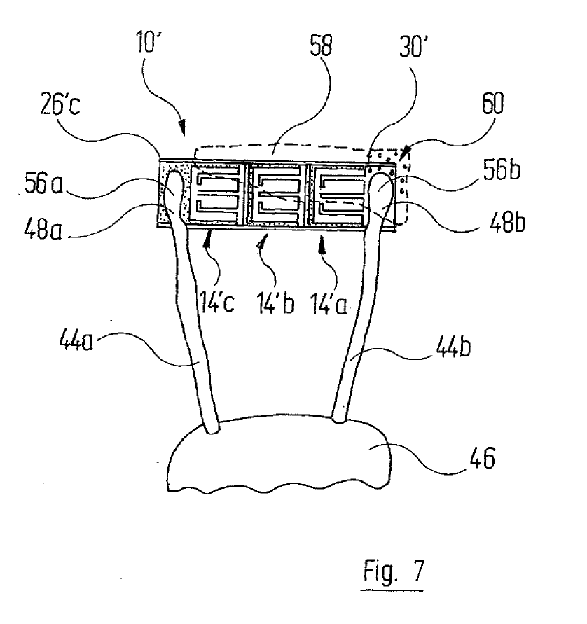

FIG. 7 shows a view corresponding to FIG. 5 of a modified illuminant according to FIG. 4, the light chip arrangement being contacted to the supply lines according to FIGS. 2A and 2B;

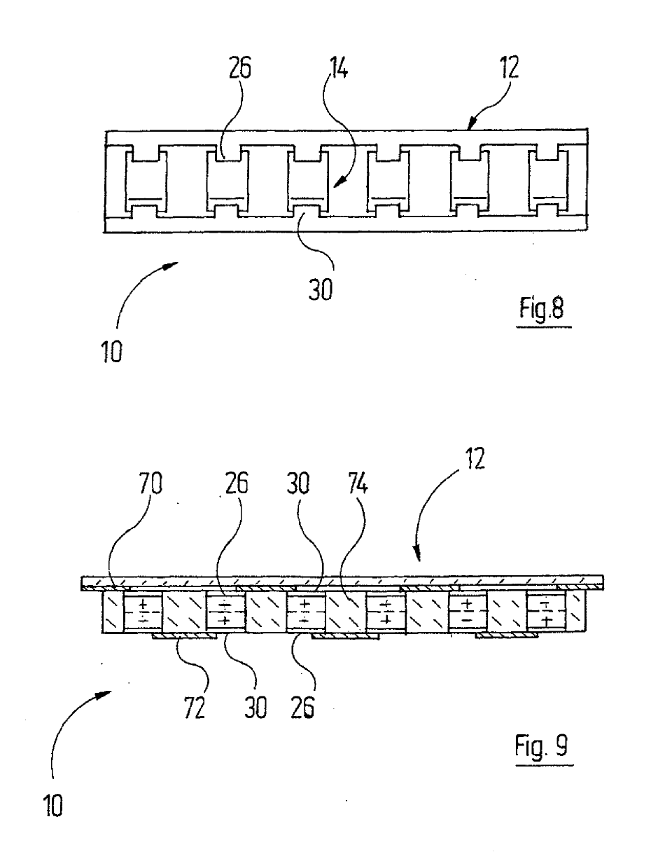

FIG. 8 shows a light chip arrangement with light-emitting semiconductor structures connected in parallel; and

FIG. 9 shows a cross-section through a modified light chip arrangement with semiconductor structures connected in series.

In FIGS. 1A and 1B, a light chip arrangement, which includes a base substrate 12 of sapphire glass, is designated as a whole by 10. Sapphire glass is also known as corundum glass (Al₂O₃ glass). In the case of the light chip arrangement 10, the base substrate 12 has a thickness of about 400 μm, but it can also have other thicknesses, which for instance can be between 5 μm and 600 μm. Instead of the sapphire glass, a less expensive material in the form of a high-temperature-resistant glass such as Pyrex glass can be used for the base substrate 12.

The base substrate 12 supports a semiconductor structure 14, which itself comprises three layers.

A lower layer 16, which is adjacent to the base substrate 12 of sapphire glass, is an n-conducting layer consisting of, for instance, n-GaN or n-InGaN.

A middle layer 18 is an MQW layer. MQW is the abbreviation for “Multiple Quantum Well”. An MQW material represents a superlattice, which has an electronic band structure which is changed according to the superlattice structure, and emits light at different wavelengths accordingly. The spectrum of the radiation which the p-n semiconductor structure 14 emits can be influenced by the choice of the MQW layer.

An upper layer 20 is produced from a p-conducting III-V semiconductor material, e.g. from p-GaN.

The semiconductor structure 14 has a surrounding step 22, which is U-shaped in plan view, and the step surface 24 of which is at the level between the base substrate 12 and the MQW layer 18. In this way, the n-conducting layer 16 in the region of the step surface 24 projects laterally beyond the MQW layer 18 and the p-conducting layer 20. The step surface 24 is covered by a correspondingly U-shaped vapour-deposited track 26, with two parallel running tracks 26a and 26b and a track 26c running perpendicularly to them. The track 26c forms a contact connection to the n-conducting layer 16.

To contact also the p-conducting layer 20, on its upper side, next to the region 28, which seen from above is flanked laterally by the U-shaped track 26, a conducting surface 30 is vapour-deposited, forming a contact connection to the p-conducting layer 20. From the conducting surface 30, on the surface of the p-conducting layer 20, three tracks 32a, 32b, 32c, which run parallel at first, extend into the region 28 of the p-conducting layer 20. The free ends of the two outer tracks 32a and 32c are each angled by 90° in the direction of the middle track 32b, as can easily be seen in FIG. 1A.

The region 28 of the semiconductor structure 14 has an extent of from 280 μm×280 μm to 1,800 μm×1,800 μm.

The tracks 26a, 26b, 26c and 32a, 32b, 32c and the conducting surface 30 are obtained by vapour deposition of a copper-gold alloy. Alternatively, silver or aluminium alloys can also be used. In the region of the contact connections 26c and 30, gold, which is doped in a way which is known per se for connection to a p-conducting layer or n-conducting layer, can be provided.

In FIGS. 2A and 2B, a modified light chip arrangement 10′ is shown. Components which correspond to those of the light chip arrangement 10 according to FIGS. 1A and 1B have the same reference symbol with an added prime.

In the case of the light chip arrangement 10′, three semiconductor structures 14′a, 14′b and 14′c are provided, corresponding essentially to the semiconductor structure 14 according to FIGS. 1A and 1B. The semiconductor structures 14′a, 14′b and 14′c are connected in series, the conducting surface 30′ of the middle semiconductor structure 14′b being connected to the track 26′c of the semiconductor structure 14′a, and the track 26′c of the semiconductor structure 14′b being connected to the conducting surface 30′ of the semiconductor structure 14′c.

A preferred implementation of the connection between a track 26′c and a conducting surface 30′ is shown in FIG. 3, in more detail at an enlarged scale, using the example of the connection between the semiconductor structures 14′b and 14′c (see FIG. 2A).

Between the semiconductor structures 14′b and 14′c, a ramp-shaped insulator 34 is provided. For this purpose, for instance, an electrically insulating material can be sputtered on between the appropriate semiconductor structures 14′. The gap between two semiconductor structures 14′, in FIG. 3 the semiconductor structures 14′b and 14′c, is of the order of magnitude of 100 μm.

On the ramp-shaped insulator 34, a track 36 is vapour-deposited, and can, for instance, consist of the same material as was explained above in relation to the tracks 26 and 32 and the conducting surface 30.

Because of the ramp shape, even thickness of the vapour-deposited track is ensured. There are no shaded areas such as would be expected in the case of track sections running perpendicularly to the plane of the base substrate 12.

A secure, durable conducting connection between the semiconductor structures 14′ is ensured by the track 36. Traditionally used bonding structures with extremely thin bonding wires do not resist thermal and/or mechanical stress as well.

As can be seen in FIG. 3, there the semiconductor structure 14′c is somewhat modified, and a recess 38, filled with the insulating material of the ramp 34, is provided below the track 36.

In FIG. 4, an illuminant 40, which as a connector base 42 has a standardised bayonet base, is shown. Instead of the bayonet base (such as a GU10 base and similar), a standardised Edison base (e.g. E12, E26 and similar), a standardised dual in-line plug base or a standardised wedge base can be provided.

From the outer connection regions (which are not specifically identified by a reference symbol, and which are known per se) of the connector base 42, two supply lines 44a, 44b run in its interior. Above the connector base 42, these pass through a spacer 46 of an electrically insulating material. This prevents the supply lines 44a, 44b touching each other, which would cause a short circuit.

The free ends 48a and 48b of the supply lines 44a and 44b respectively form contact regions which contact a light chip arrangement 10 or 10′, this being only indicated in FIG. 4.

The illuminant 40 includes a bulb 50 of a translucent material, which in the mounted state, together with the connector base 42, delimits an inner chamber 52 of the illuminant 40.

The bulb 50 is, for instance, of glass or an epoxy resin, and if desired can also fulfil the function of a collecting optical system.

The inner chamber 52 is filled with a silicone oil 54, through which heat which the light chip arrangement 10 or 10′ generates is conducted away to the radially outer region of the bulb 50.

Also for the purpose of conducting heat away, the supply lines 44a, 44b, in addition to their electrical conductivity, have good thermal conductivity, which should preferably correspond at least to that of copper.

So that satisfactory heat conduction can take place via the supply lines 44a, 44b, they have a diameter of 0.3 mm to 2 mm, preferably between 0.5 and 1.0 mm, preferably again about 0.7 mm.

In FIG. 5, in an enlarged view, how the light chip arrangement 10 is contacted with a single semiconductor structure 14 between the contact regions 48a, 48b of the supply lines 44a, 44b is shown. As can be seen there, the contact region 48a of the supply line 44a is contacted onto the track 26c of the semiconductor structure 14 by brazing by means of a silver solder 56a. Its conducting surface 30 is also connected via a silver solder, designated by 56b, to the contact region 48b of the second supply line 44b of the illuminant 40.

Instead of the silver solder 56a, 56b for contacting the light chip arrangement 10, the contact regions 48a, 48b of the supply lines 44a, 44b can also be conductingly connected to the corresponding track 26c or conducting surface 30 of the semiconductor structure 14 by means of an electrically conducting adhesive.

In a modification shown in FIG. 6, the light chip arrangement 10 is additionally sheathed with a transparent material 58, in which phosphor particles 60, indicated by dots, are homogeneously distributed. The material 58 can be, for instance, a transparent two-component adhesive. The material 58 is shown in a broken-open view. However, the light chip arrangement 10 is actually completely sheathed by the material 58.

When a voltage is applied, the semiconductor structure 14 radiates ultraviolet light and blue light in a wavelength range from 420 nm to 480 nm. Because of the material layer 58, with the phosphor particles 60, in which the light chip arrangement 10 is sheathed, a white light LED can be obtained. Suitable phosphor particles 60 are produced from transparent solid materials which have colour centres. To convert the ultraviolet and blue light which the semiconductor structure 14 emits into white light, three kinds of phosphor particle 60, which partially absorb the ultraviolet and blue light and themselves emit in the yellow and red, are used. Additionally, if desired, phosphor particles which emit in the blue can be added to the mixture.

Changing the spectrum of the light which the illuminant 40 generates is also possible by constructing the semiconductor structure 14 from layers 16, 18 and 20, which are formed from known materials other than those given here.

Alternatively to the material 58 with the phosphor particles 60, the latter can also be provided homogeneously distributed in the silicone oil 54 in the inner chamber 52 of the illuminant 40.

With a modification of the illuminant 40, it is also possible to do without the silicone oil 54. In this case, for instance, the inner surface of the inner chamber 52 of the bulb 50 could be coated with a layer of material 58 with phosphor particles 60 of the kind explained above.

The phosphor particles 60, or the material 58 which receives them, can also be applied externally on a transparent plastic or glass sheath, which is in such a form that it surrounds the semiconductor structure 14 of a light chip arrangement 10 or 10′, which is inserted into the sheath, in all spatial directions at essentially the same distance.

An advantageous distance between the material 58, in which the phosphor particles 60 are homogeneously distributed, and the semiconductor structure 14 is between about 0.3 mm and 3.0 mm, preferably 0.5 and 1.5 mm, preferably about 1 mm.

In FIG. 7, the contacting of the light chip arrangement 10′ with the three semiconductor structures 14′a, 14′b and 14′c via the supply lines 44a, 44b is shown at an enlarged scale. Apart from the light chip arrangement 10′ being provided there, what is said above about the contacting of the light chip arrangement 10 applies correspondingly, mutatis mutandis. The light chip arrangement 10′ too can be sheathed in a material 58 in which phosphor particles 60 are homogeneously distributed, to achieve white light radiation. The material 58 is indicated in FIG. 7 by dashes.

The illuminant 40 in this form, with the light chip arrangement 10 or 10′, is twisted or plugged into a suitable holder of corresponding form for operation with its connector base 42. Via the connector base 42, an operating voltage is applied to the supply lines 44a, 44b, and via them to the corresponding light chip arrangement 10 or 10′, so that the corresponding semiconductor structures 14 and 14′ are stimulated to shine.

The explained semiconductor structures 14 and 14′, and the corresponding light chip arrangement 10 or 10′, are characterized by a long lifetime with high luminosity. In this way, illuminants which have a long lifetime, and which can replace standardised illuminants with a shorter lifetime, are achieved, without the necessity, for instance, of making structural changes to associated lampholders.

Each semiconductor structure 14 or 14′ is operated with an operating voltage of about 3.5 to 4 V, so that the light chip arrangement 10, which is formed of three semiconductor structures 14′a, 14′b and 14′c, can be operated with 12 V. This is a great advantage, in particular for the motor vehicle sector.

Within the connector base 42, if required, additional electronic components such as one or more appropriate series resistors or similar, which are connected between the outer connection regions of the connector base 42 and the supply lines 44a, 44b and ensure an essentially constant operating amperage to the semiconductor structures 14 and 14′, can be provided. Additionally, within the connector base 42, electronic components by which an external supply voltage which differs from the required operating voltage of the semiconductor structures 14 and 14′, such as a mains voltage, is transformed to the required operating voltage, can be provided.

With 1 W power consumption, each semiconductor structure 14 or 14′ achieves a light output of about 40 lumens.

In the case of the light chip arrangement according to FIG. 8, on one base substrate 12 six light-emitting semiconductor structures 14, which are connected electrically parallel to each other as the result of the contacting through connections 36, are provided.

In the case of the light chip arrangement 10 according to FIG. 9, on one base substrate 12 six semiconductor structures 14, which are adjacent to the base substrate 12 alternately with their n-layer and their p-layer, which both carry transparent electrodes 26, 30, are arranged. They can therefore be connected in series by tracks 70 and 72 which run parallel to the substrate plane, and which can easily be generated in the required thickness and uniformity by vapour deposition.

The spaces between the semiconductor structures 14 are filled with transparent insulating material volumes 74. These can be obtained by screening glass frit and then fusing together or sintering the frit.

1. An electrical connection between a semiconductor structure and another structure, having a first terminal, which belongs to the semiconductor structure, and a second terminal, which belongs to the other structure, and having a connecting track of electrically conductive material, which extends from the first terminal to the second terminal,
wherein the first terminal and the second terminal take the form of flat contact zones and the connecting track is made of an electrically conductive plastics material film, which covers the two contact zones at least partially in a bonded manner.

2. A connection according to claim 1,
wherein the contact zones comprise an area of at least 2 mm².

3. A connection according to claim 1,
wherein the plastics material film has a thickness of about 20 μm to about 200 μm.

4. A connection according to claim 1,
wherein the plastics material film comprises a filling of fine electrically conductive particles, which is incorporated into a plastics matrix.

5. A connection according to claim 4,
wherein the particles have a size of 10 μm to 100 μm.

6. A connection according to claim 4,
wherein the plastics matrix is electrically conductive.

7. A connection according to claim 1,
wherein the plastics material film is elastic.

8. A connection according to claim 1,
wherein the plastics material film exhibits at least one of the following properties: elasticity, plasticity, resistance to low temperatures down to −40° C., resistance to high temperatures up to 200° C.

9. A connection according to claim 1,
wherein the plastics material film comprises at least one material from the following group: natural and synthetic elastomers, epoxy resins, acrylates, urethanes.

10. A connection according to claim 1,
wherein an insulating support is provided between the terminals, the top of which forms a recess-free, preferably smooth connection between the terminals.

11. A method of producing an electrical connection between at least one contact zone of one semiconductor structure and at least one contact zone of at least one other structure, the semiconductor structure preferably being such a structure which emits electromagnetic radiation when voltage is applied thereto,
the method comprising the following steps
a) arranging the semiconductor structure and the other structure in a predetermined fixed spatial relationship to one another;
b) applying a viscous, pasty or pulverulent connector track material to a conductor track region, which at least partially overlaps the contact zones of the semiconductor structure and other structure, the conductor track being electrically conductive or being capable of bring made electrically conductive by subsequent treatment; and
c) subsequent treatment of the conductor track material applied to the arrangement of a plurality of semiconductor structures to form a cohesive conducting material web.

12. A method according to claim 11,
wherein the conductor track material comprises a curable material and the subsequent treatment is curing and/or the conductor track material comprises a fusible material and the subsequent treatment is heat treatment.

13. A method according to claim 12,
wherein the viscous curable material used is a two-component adhesive.

14. A method according to claim 12,
wherein the conductor track material comprises fine particles of a metal with good electrical conductivity, which are preferably dispersed homogeneously in the curable material.

15. A method according to claim 12,
wherein the viscous curable material is selected from the following group: epoxy resins, acrylates, urethanes.

16. A method according to claim 11,
wherein, prior to method step b), a base layer of electrically insulating, viscous, pasty or pulverulent base layer material is applied to the semiconductor structure and/or the other structure in a region comprising at least part of a conductor track zone, which base material may be converted by subsequent treatment into a cohesive layer.

17. A method according to claim 16,
wherein the base layer material comprises a curable material and the subsequent treatment is curing and/or the base layer material comprises a fusible material and the subsequent treatment is heat treatment.

18. A method according to claim 16,
wherein subsequent treatment of the applied base layer proceeds before application of the conductor track material.

19. A method according to claim 11,
wherein, prior to the performance of step b) or after step b) or after step c), a viscous, pasty or pulverulent sealing material, which may be converted by subsequent treatment into a cohesive layer, is applied to the arrangement of semiconductor structures, the contact zones being left free.

20. A method according to claim 19,
wherein the sealing material comprises a curable material and the subsequent treatment is curing and/or the sealing material comprises a fusible material and the subsequent treatment is heat treatment.

21. A method according to claim 20,
wherein the sealing material takes the form of a varnish.

22. A method according to claim 19,
wherein the sealing material is transparent when cured.

23. A connection according to claim 1, wherein the contact zones comprise an area of 3 to 10 mm².

24. A connection according to claim 1, wherein the plastics film has a thickness of about 40 μm to about 100 μm.

25. A connection according to claim 4, wherein the particles have a size of 20 μm to 50 μm.

26. A method according to claim 14, wherein the fine particles comprise gold, copper and/or silver particles.
